(19) United States
(12) Patent Application Publication
(10) Pub. No.: US 2026/0235656 A1
(43) Pub. Date: Aug. 13, 2026

(54) SYSTEM AND METHOD FOR ARC FAULT DETECTION IN AN ELECTRICAL NETWORK

(71) Applicant: ABB Schweiz AG, Baden (CH)

(72) Inventors: Hetul Patel, Waterford, CT (US); Maggie Shao, West Hartford, CT (US); Cecil Rivers, West Hartford, CT (US); Benjamin Francis, Bloomfield, CT (US)

(21) Appl. No.: 19/048,561

(22) Filed: Feb. 7, 2025

(51) Int. Cl. G01R 31/14

(52) U.S. Cl. CPC G01R 31/14

(57) ABSTRACT

An apparatus for detecting an arc-fault in an electrical network includes a current sensor and at least one processor. The current sensor is configured to sense a current signal of the electrical network. The processor is configured to calculate a plurality of features that identify characteristics of the current signal; process, by each of a plurality of arc-fault detection algorithms, the plurality of features to generate a plurality of values; generate a plurality of trip decisions, each trip decision of the plurality of trip decisions based on whether a corresponding value of the plurality of values exceeds a pre-determined threshold; generate a vote result based on a vote from each of the plurality of trip decisions; determine whether to generate a trip signal based on the vote result; and generate the trip signal to trip a circuit breaker based on the determination.

### TECHNICAL FIELD

The present disclosure relates to a method and systems for arc-fault detection, and more particularly, detecting arc-fault events utilizing multiple algorithms.

### BACKGROUND

Arc-fault detection devices prevent electrical installations from producing fire hazards induced by electrical arcs associated with damaged cables and connectors. These arc-fault devices are typically comprised of an arc-fault detection stage that monitors the currents on the electrical network, and a switch for interrupting the currents when arc-fault events are detected. In an electrical network, an arcing load is characterized by electricity conducting across a gap in a connection, creating a discharge of energy. This phenomenon can occur under certain conditions, leading to potential hazards such as equipment damage or fire. Some electrical loads, such as light emitting diode (LED) lights, motorized loads, heaters, etc., can mimic these arcing characteristics during normal operation.

An arc fault circuit interrupter (AFCI) can be used to detect arcing in a dwelling. Ideally, the AFCI would precisely trip during arcing events and would not trip during non-arcing events. However, false trips or commonly known as nuisance trips are frequently experienced in response to the occurrence of arc-mimicking loads . The nuisance trips are undesirable.

Thus, there is a need to improve the accuracy of the arc-fault detecting and to minimize false trips for non-arcing loads.

### BRIEF DESCRIPTION

In one embodiment, an apparatus for detecting an arc-fault in an electrical network is provided. The apparatus for detecting the arc-fault includes a current sensor and at least one processor. The current sensor is configured to sense a current signal of the electrical network. The at least one processor is configured to calculate a plurality of features that identify characteristics of the current signal; process, by each of a plurality of arc-fault detection algorithms, the plurality of features to generate a plurality of values, each value of the plurality of values associated with a different one of the plurality of arc-fault detection algorithms; generate a plurality of trip decisions, each trip decision of the plurality of trip decisions based on whether a corresponding value of the plurality of values exceeds a pre-determined threshold; generate a vote result based on a vote from each of the plurality of trip decisions; determine whether to generate a trip signal based on the vote result; and generate the trip signal to trip a circuit breaker based on the determination.

In another embodiment, a method for detecting an arc-fault in an electrical network is provided. The method includes sensing a current signal of the electrical network; calculating a plurality of features that identify characteristics of the current signal; processing, by each of a plurality of arc-fault detection algorithms, the plurality of features to generate a plurality of values, each value of the plurality of values associated with a different one of the plurality of arc-fault detection algorithms; generating a plurality of trip decisions, each trip decision of the plurality of trip decisions based on whether a corresponding value of the plurality of values exceeds a pre-determined threshold; generating a vote result based on a vote from each of the plurality of trip decisions; and determining whether to generate a trip signal based on the vote result.

In another embodiment, an arc-fault protection device for interrupting a current in an electrical network is provided. The arc-fault protection device includes a current sensor, at least one processor, a trip mechanism, and at least one memory. The current sensor is configured to sense the current of the electrical network. The trip mechanism is configured to trip a circuit breaker of the electrical network in response to receiving a trip signal. The at least one memory stores programmed instructions which, when executed by the at least one processor, cause the at least one processor to calculate one or more features that identify characteristics of the current of the electrical network; process, by each of one or more arc-fault detection algorithms, the one or more features to generate one or more values, each value of the one or more values associated with a different one of the one or more arc-fault detection algorithms; generate one or more trip decisions, each trip decision of the one or more trip decisions based on whether a corresponding value of the one or more values exceeds a pre-determined threshold; determine whether to generate the trip signal to trip the circuit breaker based on the one or more trip decisions; and generate the trip signal based on the determination.

### BRIEF DESCRIPTION OF DRAWINGS

These and other features, aspects, and advantages of the present disclosure will become better understood when the following detailed description is read with reference to the accompanying drawings in which like characters represent like parts throughout the drawings.

FIG. 1 depicts a schematic architecture for arc-fault detection in an exemplary embodiment.

FIG. 2 depicts a flow diagram for a trip decision in an electrical network in an exemplary embodiment.

FIG. 3 is a flow chart of a method for detecting an arc-fault in an electrical network in an exemplary embodiment.

FIG. 4 depicts a simplified block diagram of a system for detecting an arc-fault in an exemplary embodiment.

Unless otherwise indicated, the drawings provided herein are meant to illustrate features of embodiments of this disclosure. These features are believed to be applicable in a wide variety of systems comprising one or more embodiments of this disclosure. As such, the drawings are not meant to include all conventional features known by those of ordinary skill in the art to be required for the practice of the embodiments disclosed herein.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately”, and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

As used herein, the terms “processor” and “computer,” and related terms, e.g., “processing device,” “computing device,” and “controller” are not limited to just those integrated circuits referred to in the art as a computer, but broadly refers to a microcontroller, a microcomputer, an analog computer, a programmable logic controller (PLC), an application specific integrated circuit (ASIC), and other programmable circuits, and these terms are used interchangeably herein. In the embodiments described herein, “memory” may include, but is not limited to, a computer-readable medium, such as a random-access memory (RAM), a computer-readable non-volatile medium, such as a flash memory. Alternatively, a floppy disk, a compact disc – read only memory (CD-ROM), a magneto-optical disk (MOD), and/or a digital versatile disc (DVD) may also be used. Also, in the embodiments described herein, additional input channels may be, but are not limited to, computer peripherals associated with an operator interface such as a touchscreen, a mouse, and a keyboard. Alternatively, other computer peripherals may also be used that may include, for example, but not be limited to, a scanner. Furthermore, in the example embodiment, additional output channels may include, but not be limited to, an operator interface monitor or heads-up display. Some embodiments involve the use of one or more electronic or computing devices. Such devices typically include a processor, processing device, or controller, such as a general purpose central processing unit (CPU), a graphics processing unit (GPU), a microcontroller, a reduced instruction set computer (RISC) processor, an ASIC, a programmable logic controller (PLC), a field programmable gate array (FPGA), a digital signal processing (DSP) device, and/or any other circuit or processing device capable of executing the functions described herein. The methods described herein may be encoded as executable instructions embodied in a computer readable medium, including, without limitation, a storage device and/or a memory device. Such instructions, when executed by a processing device, cause the processing device to perform at least a portion of the methods described herein. The above examples are not intended to limit in any way the definition and/or meaning of the term processor and processing device.

As discussed previously, preventing false trips for non-arcing loads is desirable, as it prevents unnecessarily interrupting power to loads that are non-arcing, such as LED lights, low-power fans, heaters, etc.

Training or developing an algorithm to detect arcing is a challenging task due to variation in arcing and the large number of loads that mimic arcing. An algorithm that is trained or developed on a set of appliances and arcing may not be relied upon to make the correct arcing decision when the algorithm is applied to new or different loads. For example, training an algorithm on motorized devices such as drills, vacuums, etc., may enable the algorithm to operate correctly to generate the correct trip decisions with other motorized devices. If the algorithm encounters a different type of load that mimics arcing, e.g., lights on dimmers, the algorithm may not operate correctly and as a result may generate a false trip determination. In another example, if an arc detection algorithm is developed for devices such as microwaves, toasters, dishwashers, refrigerators, and ovens, when an appliance of a different type is introduced as a load, the algorithm can potentially falsely determine there is arcing or non-arcing since the algorithm was tuned for a specific data set.

Further, multiple algorithms can be trained based on various groups of appliances. If it is necessary to change the algorithm to align with load associated with the appliances in use, switching of the algorithm may require manual intervention. Additional issues may further complicate the algorithm transition from a current algorithm to a different algorithm. For example, a switching mechanism may be needed to select the algorithm of choice. The arc-fault device interrupter may need to be reset whenever a new algorithm is needed and implemented. Selecting the correct algorithm for a particular use may be an imprecise, iterative proves where the operator estimates which algorithm would work in a specific application. Blind switching to a different algorithm may occur after a false detection is experienced.

In the embodiments described herein, a plurality of algorithms are used to analyze a current signal in an electrical network. In some embodiments, each of the algorithms is trained using arc-fault events generated by different types of loads. Thus, each of the arc-fault detection algorithms is trained to detect arc-faults and distinguish the arc-faults from non-arcing current signals of a predetermined group of loads. In the embodiments described herein, a plurality of features are calculated that identify characteristics of the current signal in the electrical network. The plurality of features are processed by the algorithms, which generate values that are used to generate trip decisions. A vote result may be generated based on the trip decisions, and determining whether to trip a circuit breaker of the electrical network may be based on the vote result. For example, a decision to trip the circuit breaker may be performed in response to unanimous vote, a majority vote, a weighted majority vote, etc. The use of multiple algorithms for determining when to trip the circuit breaker improves the reliability of the electrical network by reducing the number of false trips that may occur in conventional AFCI implementations.

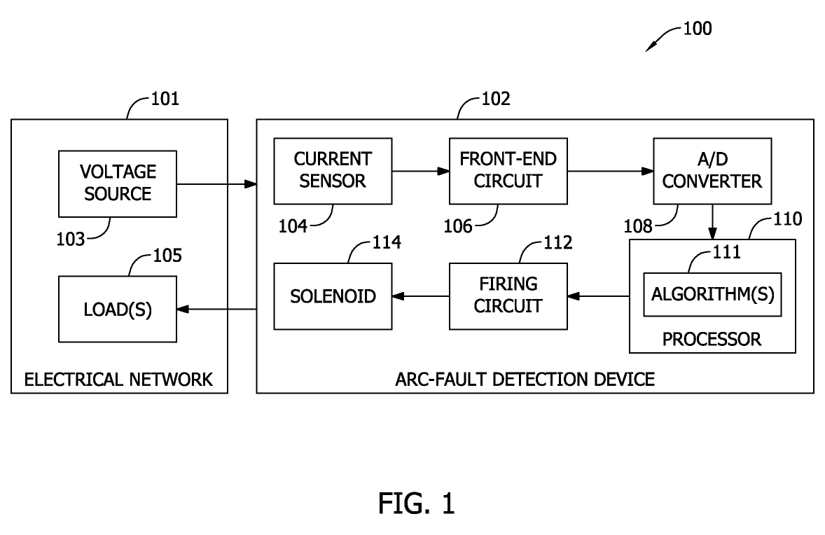

FIG. 1 illustrates a schematic architecture for an arc-fault detection system 100 in an exemplary embodiment. In this embodiment, arc-fault detection system 100 includes an electrical network 101 and an arc-fault detection device 102. Electrical network 101 includes a voltage source 103 and electrical loads 105. Voltage source 103 may represent the line voltage, and load current may flow through electrical network 101. Electrical loads 105 may be an electrical component or portion of a circuit that consumes electric power, for example, electrical appliances and lights in a dwelling.

Arc-fault detection device 102 may be, for example, an apparatus for detecting an arc-fault, or an AFCI. In some embodiments, the apparatus for detecting an arc-fault may be a dual function circuit interrupter (DFCI), which, for example, combines both ground fault circuit interrupter (GFCI) and arc fault circuit interrupter (AFCI) protection in a single breaker. As shown in FIG. 1, arc-fault detection device 102 may include a current sensor 104, a front-end circuit 106, an analog-to-digital converter 108, a processor 110 storing arc-fault detection algorithms 111, a firing circuit 112, and a solenoid 114. In some embodiments, firing circuit 112 and solenoid 114 may be referred to as a trip mechanism.

Current sensor 104 senses and measures a current signal of electrical network 101, for example, the load current flowing through electrical network 101. In some embodiments, current sensor 104 may be configured to convert the current signal to a voltage signal. After the current signal is sensed and measured by current sensor 104, the current signal passes through front-end circuit 106 to analog-to-digital converter 108. Front-end circuit 106 may include a low-frequency filtering and amplification component and/or a high-frequency filtering and amplification component to filter a range of frequencies of the load current signal and amplify the range of frequencies of the load current signal. In some embodiments, analog-to-digital converter 108 may convert the amplified range of frequencies of the load current signal from analog to a digitized signal using a sampling scheme.

Processor 110 may calculate a plurality of features of the sampled current signal that identify characteristics of the sampled current signal. Processor 110 then processes the features using a plurality of arc-fault detection algorithms 111 to generate a value associated with each individual arc-fault detection algorithm 111. Then a trip decision is generated by each arc-fault detection algorithm 111 based on the generated value. For example, if the generated value exceeds a predetermined threshold for a specific discrete arc-fault detection algorithm 111, the discrete arc-fault detection algorithm 111 goes into a state or mode referred to as pickup. The pickup state for the discrete arc-fault algorithm is entered when the trip criteria is met for the associated arc-fault detection algorithm 111. If all of the arc-fault detection algorithms 111 meet their thresholds, all the arc-fault detection algorithms 111 will be in pickup. Once all arc-fault detection algorithms 111 are in pickup, a count may be set. The count represents the time to trip. The count is reduced before the trip signal trips the circuit breaker. The countdown or reduction of the counter may be performed to reduce the occurrence of false trips. When the counter reaches its pre-determined trip value, e.g. “0”, a trip signal to trip the circuit breaker may be generated. If some of arc-fault detection algorithms 111 are not in pickup, the counter is not decrease or stopped, and no-trip signal is generated.

Arc-fault detection device 102 further includes a firing circuit 112. Firing circuit 112 may be a control circuit for triggering the interrupting mechanism, for example, solenoid 114, to disconnect the circuit in response to receiving the trip signal. Alternatively, the interrupting mechanism may be other mechanical switch, such as thermal-magnetic systems, motor-operated mechanisms, etc.

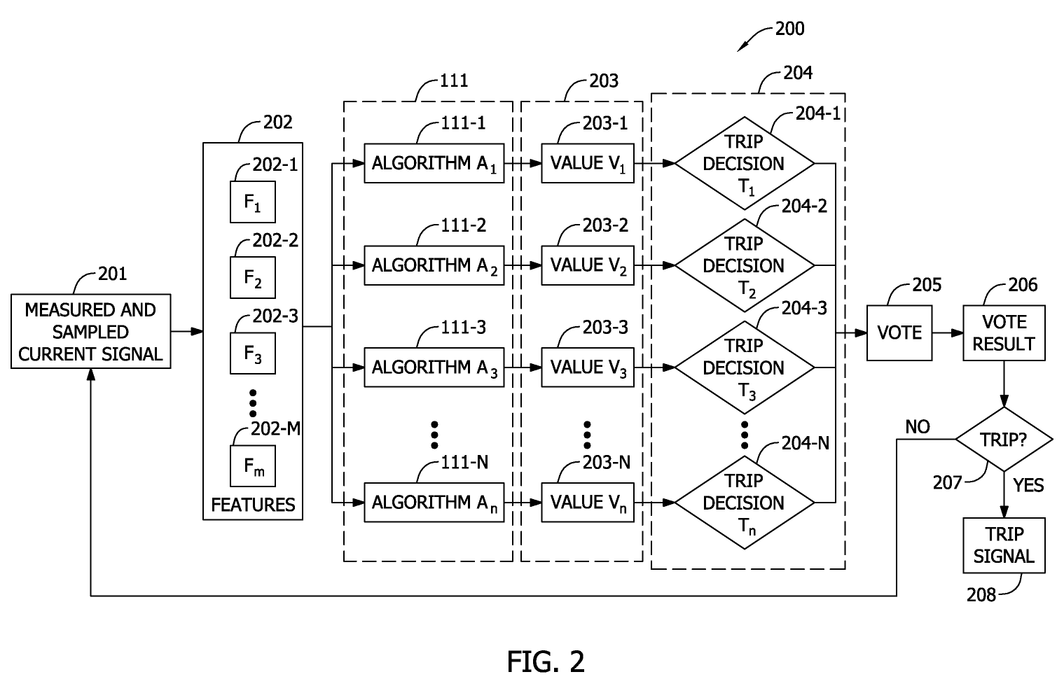

FIG. 2 depicts flow diagram 200 for a trip decision for an electrical network in an exemplary embodiment. Flow diagram 200 may be implemented by arc-fault detection device 102 of FIG. 1, or other systems, not shown. As shown in FIG. 2, after the load current signal is measured by current sensor 104 and sampled by analog-to-digital converter 108, processor 110 calculates a plurality of features 202-1, 202-2, 202-3, 202-M, collectively referred to as features 202, from the measured and sampled current signal 201 (e.g., processor 110 calculates a plurality of features 202 based on the output of analog-to-digital converter 108). Features 202, illustrated as F1, F2, F3… Fm in FIG. 2, where m is an integer, identify characteristics of the measured and sampled current signal 201. For example, features 202 may include the mean of a full cycle, the standard deviation of the full cycle, the maximum standard deviation of any window in the cycle, the minimum standard deviation of any window in the cycle, the ratio of the maximum and minimum standard deviations, the absolute sum of each sample in the cycle, the relation of the standard deviations (or variances) for each adjacent window in the cycle, or the Root Mean Square (RMS) value, etc.

Each of arc-fault detection algorithms 111-1, 111-2, 111-3, 111-N, where N is an integer, collectively referred to as arc-fault detection algorithms 111 and illustrated as A1, A2, A3… An in FIG. 2, where n is an integer, processes features 202, and generate a plurality of values 203-1, 203-2, 203-3, 203-N, collectively referred to as values 203 and illustrated as V1, V2, V3… Vn in FIG. 2, where n is an integer. In some embodiments, each of arc-fault detection algorithms 111-1, 111-2, 111-3, 111-N is trained or developed to detect arc-faults of a predetermined group of loads, which may be different loads. Alternatively, each of arc-fault detection algorithms 111-1, 111-2, 111-3, 111-N may be trained or developed to detect arc-faults of a single load.

Accordingly, each of values 203-1, 203-2, 203-3, 203-N, is associated with a different one of arc-fault detection algorithms 111-1, 111-2, 111-3, 111-N, respectively. After values 203-1, 203-2, 203-3, 203-N are calculated, processor 110 determines whether each of values 203-1, 203-2, 203-3, 203-N exceeds a predetermine threshold for the associated arc-fault detection algorithm 111-1, 111-2, 111-3, 111-N, respectively. Each trip decision 204-1, 204-2, 204-3, 204-N is associated with a corresponding value calculated by an arc fault detection algorithm. Respectively, these values associated with the trip decisions are 203-1, 203-2, 203-3 and 203-N. The magnitudes of the values are evaluated, and as a result, processor 110 generates a plurality of discrete trip decisions 204-1, 204-2, 204-3, 204-N, collectively referred to as trip decisions 204 and illustrated as T1, T2, T3… Tn in FIG. 2, where n is an integer. For example, if value 203-1 exceeds the predetermine threshold of the associated arc-fault detection algorithm 111-1, that is, trip criteria is met for arc-fault detection algorithm 111-1, then arc-fault detection algorithm 111-1 goes into pickup, and the associated trip decision 204-1, which indicates to trip the circuit breaker, is generated. If value 203-2 does not exceed the predetermine threshold of the associated arc-fault detection algorithm 111-2, that is, trip criteria is not met for arc-fault detection algorithm 111-2, arc-fault detection algorithm 111-2 will not go into pickup, and the associated trip decision 204-2, which indicates not to trip the circuit breaker, is generated.

As shown in FIG. 2, a vote 205 is performed based on trip decisions 204, and a vote result 206 is generated. Vote result 206 is used to make a determination 207 whether or not to generate a trip signal 208 that causes a circuit breaker to trip. A trip mechanism, such as a firing circuit or a solenoid, may be actuated to cause the circuit breaker to trip.

Vote 205 may be a unanimous vote, a majority vote, a weighted majority vote, etc. For example, when vote 205 is a unanimous vote, if all arc-fault detection algorithms 111 A1, A2, A3… An meet their thresholds of the trip criteria, all of arc-fault detection algorithms 111-1, 111-2, 111-3, 111-N are in pickup, and accordingly all of trip decisions 204-1, 204-2, 204-3, 204-N indicate to trip the circuit breaker. Therefore, the unanimous vote result 206, which is generated based on trip decisions 204-1, 204-2, 204-3, 204-N that indicate to trip the circuit breaker, will cause the circuit breaker to trip (e.g., trip signal 208 is generated). Otherwise, when vote 205 is a unanimous vote, if some of arc-fault detection algorithms 111, for example, arc-fault detection algorithms 111-1 and 111-3 do not meet their thresholds of the trip criteria, the corresponding arc-fault detection algorithms 111-1 and 111-3 are not in pickup, and accordingly the corresponding trip decisions 204-1, 204-3 will indicate not to trip the circuit breaker. Therefore, the unanimous vote result 206, which is generated based on all of trip decisions 204 including trip decisions 204-1, 204-3 that indicate not to trip the circuit breaker, will cause the circuit breaker not to trip (e.g., trip signal 208 is not generated).

Alternatively, vote 205 may be a majority vote, and the majority vote result 206 that trips the circuit breaker will be based on a majority of trip decisions 204-1, 204-2, 204-3, 204-N that indicate to trip the circuit breaker.

In other embodiments, vote 205 may be a weighted majority vote, each of arc-fault detection algorithms 111 is assigned with a particular weight, and the weighted majority vote result that indicates to trip the circuit breaker will be generated based on a weighted majority of trip decisions 204-1, 204-2, 204-3, 204-N that indicate to trip the circuit breaker. For example, the arc-fault detection algorithm trained to detect arc-faults of the loads in the kitchen may be assigned with a higher vote than the arc-fault detection algorithm trained to detect arc-faults of the loads in the living room, and accordingly, the loads in the kitchen will give more influence or a greater weight to the vote result that indicates whether to trip the circuit breaker.

In FIG. 2, although a plurality of features 202-1, 202-2, 202-3, 202-M, a plurality of arc-fault detection algorithms 111-1, 111-2, 111-3, 111-N, a plurality of values 203-1, 203-2, 203-3, 203-N, and a plurality of trip decisions 204-1, 204-2, 204-3, 204-N are shown in the arc-fault detection device or system, any suitable number of features 202, algorithms 111, values 203, and trip decisions 204 can be included in the arc-fault detection device or system. In some embodiments, the arc-fault detection device or system may calculates one feature that identify characteristics of the current signal, process the feature by an arc-fault detection algorithm to generate a value, and then generate a trip decision accordingly.

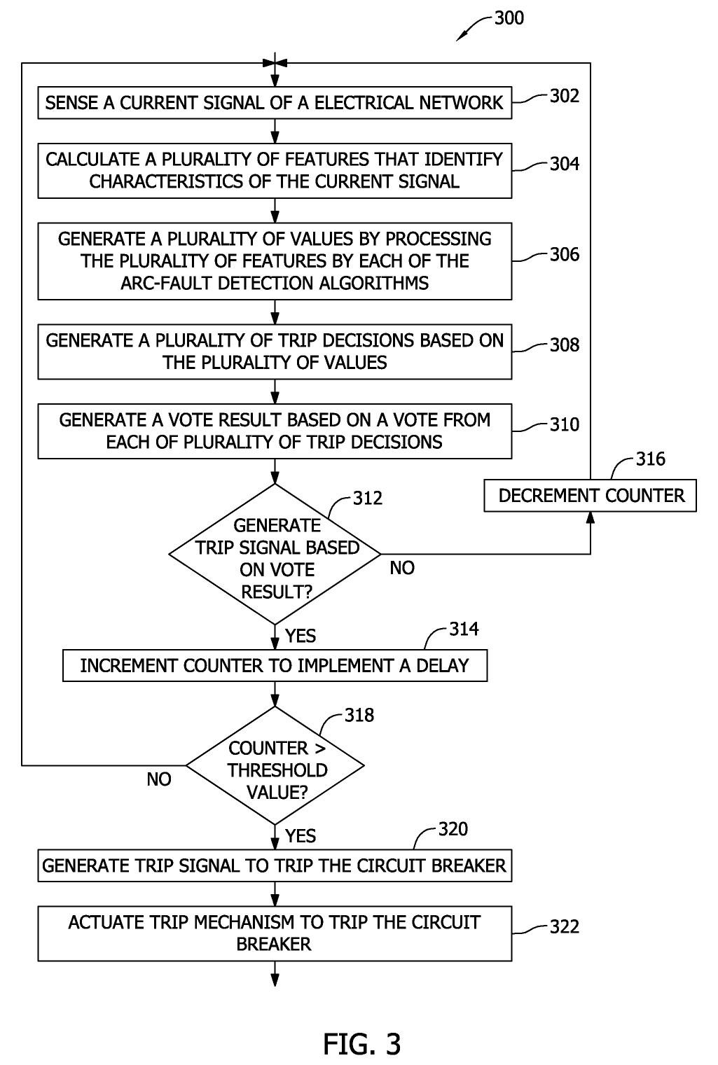

FIG. 3 is a flow chart of a method 300 for detecting an arc-fault in an electrical network in an exemplary embodiment. Method 300 will be described with respect to arc-fault detection device 102 and flow diagram 200 of FIGS. 1 and 2, respectively, although method 300 may be performed by other systems not shown.

As shown in FIG. 3, at 302, current sensor 104 senses and measures a load current signal of electrical network 101. At 304, processor 110 calculates a plurality of features 202 that identify characteristics of the load current signal. For example, features 202 may include one or more of the mean of a full cycle, the standard deviation of the full cycle, the maximum standard deviation of any window in the cycle, the minimum standard deviation of any window in the cycle, the ratio of the maximum and minimum standard deviations, the absolute sum of each sample in the cycle, the relation of the standard deviations (or variances) for each adjacent window in the cycle, or the RMS value, etc. At 306, features 202 are processed by each of the arc-fault detection algorithms 111, and arc-fault detection algorithms 111 generate values 203, respectively, such that each value 203 is associated with a different one of arc-fault detection algorithms 111.

At 308, processor 110 generates trip decisions 204 based on a determination whether each value 203 exceeds a pre-determined threshold of the associated arc-fault detection algorithm 111. For example, if value 203 exceeds the predetermine threshold of the associated arc-fault detection algorithm 111, that is, trip criteria is met for the associated arc-fault detection algorithm 111, then arc-fault detection algorithm 111 goes into pickup, and trip decision 204 indicating to trip the circuit breaker will be generated for the associated arc-fault detection algorithm 111. Otherwise, if value 203 does not exceed the predetermine threshold of the associated arc-fault detection algorithm 111, that is, trip criteria is not met for the associated arc-fault detection algorithm 111, then arc-fault detection algorithm 111 will not go into pickup, and trip decision 204 indicating not to trip the circuit breaker will be generated for the associated arc-fault detection algorithm 111.

At 310, vote result 206 is generated based on vote 205 from each of trip decisions 204. For example, when vote 205 is a unanimous vote 205, if all of trip decisions 204 indicate to trip the circuit breaker, the unanimous vote result 206 will indicate to trip the circuit breaker. Otherwise, if some of trip decisions 204 indicate not to trip the circuit breaker, the unanimous vote result 206 will indicate not to trip the circuit breaker.

Alternatively, vote 205 may be a majority vote 205 or a weighted majority vote 205. When vote 205 is a majority vote 205, the majority vote result 206 that indicates to trip the circuit breaker will be generated based on a majority of trip decisions 204 that indicate to trip the circuit breaker. In an arc fault detection system 102 that requires a majority vote to trip the circuit breaker, if the number of arc fault detection algorithms in pickup (exceeding threshold values) is equal to the number of arc fault algorithms not in pickup (below threshold values), then no trip signal will be generated to trip the circuit breaker. When vote 205 is a weighted majority vote 205, each of the arc-fault detection algorithms 111 is assigned with a particular weight, and the weighted majority vote 205 result that indicates to trip the circuit breaker will be generated based on a weighted majority of trip decisions 204 that indicate to trip the circuit breaker.

At 312, processor 110 determines whether to generate trip signal 208 based on vote result 206. If vote result 206 indicates not to trip the circuit breaker, at 316, a counter is decremented or cooled. Then processing returns to 302 of method 300. If vote result 206 indicates to trip the circuit breaker, processor 110 will, at 314, increment a counter to implement a delay before generating trip signal 208. At 318, processor 110 determines whether the counter is greater than a threshold value. If the counter is not greater than the threshold value, then processing returns to 302 of method 300. Thus, both 314 and 316 of method 300 operate to i) generate a delay before generating the trip signal 208, and ii) ensure that vote result 206 to generate trip signal 208 is not a transitory result.

If the counter is greater than the threshold counter value, then processor, at 320, generates trip signal 208 to trip the circuit breaker of the electrical network, and the circuit breaker will trip accordingly. At 322, in response to receiving the trip signal 208, a trip mechanism, such as a firing circuit 112 and a solenoid 114, is actuated to cause the circuit breaker to trip.

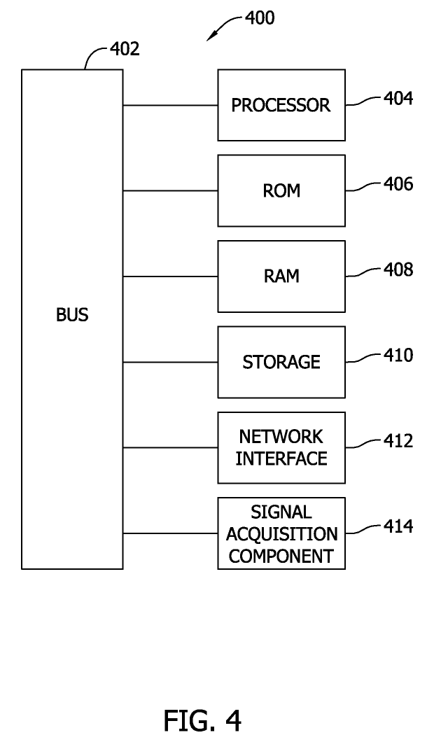

FIG. 4 depicts a simplified block diagram of a system 400 for detecting an arc-fault in an exemplary embodiment. System 400 may be used within arc-fault detection system 100 or electrical network 101 associated with a residence or business or some other building such as facility or factory. System 400 includes a processor 404, such as a central processing unit (CPU), and/or logic, that executes computer executable instructions for performing the functions, processes, and/or methods described herein. In some examples, the computer executable instructions are locally stored and accessed from a non-transitory computer readable medium, such as storage 410, which may be a hard drive or flash drive. Read Only Memory (ROM) 406 includes computer executable instructions for initializing processor 404, while random-access memory (RAM) 408 is the main memory for loading and processing instructions executed by processor 404.

Network interface 412 may connect to a wired network or cellular network and to a local area network or wide area network. System 400 may also include a bus 402 that connects processor 404, ROM 406, RAM 408, storage 410, network interface 412, and signal acquisition component 414. The components within system 400 may use bus 402 to communicate with each other. The components within system 400 are merely exemplary and might not be inclusive of every component for embodiments described herein. For example, in some embodiments, system 400 might not include network interface 412. In some embodiments, system 400 may include one or more components, such as signal acquisition component 414 for obtaining or otherwise receiving analog data such as analog data associated with a current signal of an electrical network that has been transformed to a voltage signal, had certain frequencies selected that were amplified, and converted from analog to an aliased digitized signal.

In the systems and methods of the present disclosure, multiple algorithms can focus on groups of appliances, where each group has strength in avoiding false tripping in their group. Accordingly, systems and methods provided herein allow for multiple algorithms to run concurrently and the final trip or no-trip decision is made through the result of a vote from each individual algorithm. Therefore, compared with using a single algorithm for arc detection, the systems and methods of the present disclosure improve the accuracy of the arc-fault detecting, and reduce false tripping as generating the final trip decision requires multiple algorithms making the decision based on a vote.

Further, as the final trip decision is generated based on the vote result 206 of the multiple algorithms, there is no or minimal need for users to interact or manually switch between algorithms or settings. The system 102 generates a vote result 206 without manual input or control and automatically incorporates output from all algorithms 111 to generate a final trip decision. Therefore, the systems and methods of the present disclosure minimize the need for manual intervention.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to disclose the embodiments, including the best mode, and also to enable any person skilled in the art to practice the embodiments, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. An apparatus for detecting an arc-fault in an electrical network, the apparatus comprising:
a current sensor configured to sense a current signal of the electrical network; and
at least one processor configured to:
calculate a plurality of features that identify characteristics of the current signal;
process, by each of a plurality of arc-fault detection algorithms, the plurality of features to generate a plurality of values, each value of the plurality of values associated with a different one of the plurality of arc-fault detection algorithms;
generate a plurality of trip decisions, each trip decision of the plurality of trip decisions based on whether a corresponding value of the plurality of values exceeds a pre-determined threshold;
generate a vote result based on a vote from each of the plurality of trip decisions;
determine whether to generate a trip signal based on the vote result; and
generate the trip signal to trip a circuit breaker based on the determination.

2. The apparatus according to claim 1, wherein the vote is a unanimous vote, and all of the plurality of trip decisions indicate to trip the circuit breaker.

3. The apparatus according to claim 1, wherein the vote is a majority vote, and a majority of the plurality of trip decisions indicate to trip the circuit breaker.

4. The apparatus according to claim 1, wherein the vote is a weighted majority vote, wherein each of the plurality of arc-fault detection algorithms is assigned with a particular weight, and wherein a weighted majority of the plurality of trip decisions indicate to trip the circuit breaker.

5. The apparatus according to claim 1, wherein the at least one processor is further configured to:
periodically increment a counter to implement a delay before generating the trip signal while the vote result indicates to trip the circuit breaker; and
generate the trip signal in response to the counter reaching a predetermined value.

6. The apparatus according to claim 5, wherein the at least one processor is further configured:
periodically decrement the counter while the vote result indicates not to trip the circuit breaker.

7. The apparatus according to claim 1, wherein each of the plurality of arc-fault detection algorithms is trained to detect arc-faults and distinguish the arc-faults from non-arcing current signals of a predetermined group of loads.

8. The apparatus according to claim 1, further comprising a trip mechanism configured to trip the circuit breaker of the electrical network in response to receiving the trip signal.

9. A method for detecting an arc-fault in an electrical network, the method comprising:
sensing a current signal of the electrical network;
calculating a plurality of features that identify characteristics of the current signal;
processing, by each of a plurality of arc-fault detection algorithms, the plurality of features to generate a plurality of values, each value of the plurality of values associated with a different one of the plurality of arc-fault detection algorithms;
generating a plurality of trip decisions, each trip decision of the plurality of trip decisions based on whether a corresponding value of the plurality of values exceeds a pre-determined threshold;
generating a vote result based on a vote from each of the plurality of trip decisions; and
determining whether to generate a trip signal based on the vote result.

10. The method according to claim 9, wherein the vote is selected from the group consisting of a unanimous vote, a majority vote, and a weighted majority vote.

11. The method according to claim 9, further comprising:
tripping a circuit breaker of the electrical network in response to the trip signal being generated.

12. The method according to claim 9, wherein determining whether to generate the trip signal further comprises:
periodically incrementing a counter to implement a delay before generating the trip signal while the vote result indicates to trip the circuit breaker;
generating the trip signal in response to the counter reaching a predetermined value; and
periodically decrementing the counter while the vote result indicates not to trip the circuit breaker.

13. The method according to claim 9, wherein each of the plurality of arc-fault detection algorithms is trained to detect arc-faults and distinguish the arc-faults from non-arcing current signals of a predetermined group of loads.

14. An arc-fault protection device for interrupting a current in an electrical network, comprising:
a current sensor configured to sense the current of the electrical network;
at least one processor;
a trip mechanism configured to trip a circuit breaker of the electrical network in response to receiving a trip signal; and
at least one memory storing programmed instructions which, when executed by the at least one processor, cause the at least one processor to:
calculate one or more features that identify characteristics of the current of the electrical network;
process, by each of one or more arc-fault detection algorithms, the one or more features to generate one or more values, each value of the one or more values associated with a different one of the one or more arc-fault detection algorithms;
generate one or more trip decisions, each trip decision of the one or more trip decisions based on whether a corresponding value of the one or more values exceeds a pre-determined threshold;
determine whether to generate the trip signal to trip the circuit breaker based on the one or more trip decisions; and
generate the trip signal based on the determination.

15. The arc-fault protection device according to claim 14, wherein the programmed instructions further cause the at least one processor to:
generate the trip signal in response to determining that all of the one or more trip decisions indicate to trip the circuit breaker.

16. The arc-fault protection device according to claim 14, wherein the programmed instructions further cause the at least one processor to:
generate the trip signal in response to determining that a majority of the one or more trip decisions indicate to trip the circuit breaker.

17. The arc-fault protection device according to claim 14, wherein:
each of the one or more arc-fault detection algorithms is assigned with a particular weight, and
the programmed instructions further cause the at least one processor to generate the trip signal in response to determining that a weighted majority of the one or more trip decisions indicate to trip the circuit breaker.

18. The arc-fault protection device according to claim 14, wherein the programmed instructions further cause the at least one processor to:
periodically increment a counter to implement a delay before generating the trip signal while the one or more trip decisions indicate to trip the circuit breaker;
generate the trip signal in response to the counter reaching a predetermined value; and
periodically decrement the counter while the one or more trip decisions indicate not to trip the circuit breaker.

19. The arc-fault protection device according to claim 14,
wherein the one or more features comprise one feature, the one or more arc-fault detection algorithms comprise one arc-fault detection algorithm, the one or more values comprise one value, and the one or more trip decisions comprise one trip decision.

20. The arc-fault protection device according to claim 14, wherein the arc-fault protection device is an arc-fault circuit interrupter (AFCI) or a dual function circuit interrupter (DFCI).
